(19) United States
(12) Patent Application Publication
(10) Pub. No.: US 2025/0159864 A1
(43) Pub. Date: May 15, 2025

(54) MEMORY DEVICE HAVING VERTICAL TRANSISTORS AND METHODS FOR FORMING THE SAME

(71) Applicant: Yangtze Memory Technologies Co., Ltd., Wuhan (CN)

(72) Inventors: Fan MING, Wuhan, Hubei (CN); Zhaoyun TANG, Wuhan, Hubei (CN)

(73) Assignee: Yangtze Memory Technologies Co., Ltd., Wuhan (CN)

(21) Appl. No.: 18/528,211

(22) Filed: Dec. 4, 2023

(30) Foreign Application Priority Data
Nov. 13, 2023 (CN) 202311521348.0

(51) Int. Cl. H10B 12/00

(52) U.S. Cl. CPC H10B 12/05; H10B 12/315

(57) ABSTRACT

a memory device includes an array of memory cells. Each memory cell includes a vertical transistor having a semiconductor body vertically extending in a first direction. Each memory cell includes a storage unit coupled to a first end of the semiconductor body and a bit line extending in a second direction perpendicular to the first direction. The bit line is connected to second ends of the semiconductor bodies of a row of the vertical transistors. The bit line includes a semiconductor epitaxial layer extending in the second direction and connected to the second ends of the semiconductor bodies of the row of the vertical transistors at a top surface of the semiconductor epitaxial layer.

### INCORPORATION BY REFERENCE

This application claims priority to Chinese Patent Application No. 202311521348.0, filed on Nov. 13, 2023, which is incorporated herein by reference in its entirety.

### TECHNICAL FIELD

The present disclosure relates to memory devices and fabrication methods thereof.

### BACKGROUND

Planar memory cells are scaled to smaller sizes by improving process technology, circuit design, programming algorithm, and fabrication process. However, as feature sizes of the memory cells approach a lower limit, the planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

Aspects of the disclosure provide a method of fabricating a memory device. A stack including a first semiconductor layer is formed. The stack includes a second semiconductor layer over the first semiconductor layer, a third semiconductor layer over the second semiconductor layer, and a fourth semiconductor layer over the third semiconductor layer. The stack is etched through the fourth semiconductor layer, the third semiconductor layer, and the second semiconductor layer to form first trenches along a first direction and on the first semiconductor layer. The first trenches are filled with an insulating material to form trench isolations. Remaining portions of the fourth semiconductor layer, the third semiconductor layer, and the second semiconductor layer are sandwiched by neighboring trench isolations. The remaining portions of the fourth semiconductor layer and the trench isolations are etched to form second trenches on the third semiconductor layer and along a second direction perpendicular to the first direction as well as semiconductor bodies of vertical transistors extending in a third direction and being surrounded by the second trenches and the trench isolations. The third direction is perpendicular to the first direction and the second direction. The vertical transistors stand on top of the remaining portions of the third semiconductor layer. Gate structures of the vertical transistors are formed that are along the second direction and coupled to at least one side of the semiconductor bodies.

In one aspect, a memory device includes an array of memory cells. Each memory cell includes a vertical transistor having a semiconductor body vertically extending in a first direction. Each memory cell includes a storage unit coupled to a first end of the semiconductor body and a bit line extending in a second direction perpendicular to the first direction. The bit line is connected to second ends of the semiconductor bodies of a row of the vertical transistors. The bit line includes a semiconductor epitaxial layer extending in the second direction and connected to the second ends of the semiconductor bodies of the row of the vertical transistors at a top surface of the semiconductor epitaxial layer.

In one aspect, a memory system includes a memory controller, and a memory device coupled to the memory controller. The memory device includes an array of memory cells. Each memory cell includes a vertical transistor having a semiconductor body vertically extending in a first direction. Each memory cell includes a storage unit coupled to a first end of the semiconductor body and a bit line extending in a second direction perpendicular to the first direction. The bit line is connected to second ends of the semiconductor bodies of a row of the vertical transistors. The bit line includes a semiconductor epitaxial layer extending in the second direction and connected to the second ends of the semiconductor bodies of the row of the vertical transistors at a top surface of the semiconductor epitaxial layer.

### BRIEF DESCRIPTION OF THE DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a block diagram of an exemplary system having a memory device, according to some aspects of the present disclosure.

FIG. 2 illustrates a schematic diagram of a memory device including peripheral circuits and an array of memory cells each having a vertical transistor, according to some aspects of the present disclosure.

FIG. 3 illustrates a schematic circuit diagram of a memory device including peripheral circuits and an array of dynamic random-access memory (DRAM) cells, according to some aspects of the present disclosure.

FIG. 4 illustrates a schematic circuit diagram of a memory device including peripheral circuits and an array of phase-change memory (PCM) cells, according to some aspects of the present disclosure.

FIGS. 5A-5B illustrate a memory device fabrication process where semiconductor bodies 502 of vertical transistors are formed without the employment of etch-stop layers.

FIGS. 6A, 6B, and 6C illustrate a memory device fabrication process where etch-stop layers are employed to improve the bottom profile uniformity and the etch depth uniformity of the isolation trenches and the word line trenches as well as the backside bit line silicon recesses.

FIG. 7 illustrates a plan view of an array of memory cells 702 each including a vertical transistor in a memory device 700, according to some aspects of the present disclosure.

FIG. 8 illustrates a side view of a cross-section of a memory device 800 made by employing the etch-stop layers, according to some aspects of the present disclosure.

FIGS. 9A-1/9A-2/9B-1/9B-2/9C-1/9C-2 and 9D-93 illustrate a fabrication process for forming a memory device (such as the memory device 700 or 800) by using several etch-stop layers, according to some aspects of the present disclosure.

FIG. 10 illustrates a flowchart of a fabrication process 1000 for forming a 3D memory device including vertical transistors, according to some aspects of the present disclosure.

### DETAILED DESCRIPTION OF EMBODIMENTS

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for the existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

1. Memory Devices with Vertical Transistors

Transistors are used as the switch or selecting devices in the memory cells of some memory devices, such as dynamic random access memory (DRAM), phase-change memory (PCM), and ferroelectric DRAM (FRAM). However, the planar transistors commonly used in existing memory cells usually have a horizontal structure with buried word lines in the substrate and bit lines above the substrate. Since the source and drain of a planar transistor are disposed laterally at different locations, which increases the area occupied by the transistor. The design of planar transistors also complicates the arrangement of interconnected structures, such as word lines and bit lines, coupled to the memory cells, for example, limiting the pitches of the word lines and/or bit lines, thereby increasing the fabrication complexity and reducing the production yield. Moreover, because the bit lines and the storage units (e.g., capacitors or PCM elements) are arranged on the same side of the planar transistors (above the transistors and substrate), the bit line process margin is limited by the storage units, and the coupling capacitance between the bit lines and storage units, such as capacitors, are increased. Planar transistors may also suffer from a high leakage current as the saturated drain current keeps increasing, which is undesirable for the performance of memory devices.

On the other hand, the memory cell array and the peripheral circuits for controlling the memory cell array are usually arranged side-by-side in the same plane. As the number of memory cells keeps increasing, to maintain the same chip size, the dimensions of the components in the memory cell array, such as transistors, word lines, and/or bit lines, need to keep decreasing in order not to significantly reduce the memory cell array efficiency.

To address one or more of the aforementioned issues, vertical transistors can replace the planar transistors as the switch and selecting devices in a memory cell array of memory devices (e.g., DRAM, PCM, and FRAM). Compared with planar transistors, the vertically arranged transistors (e.g., the drain and source are overlapped in the plan view) can reduce the area of the transistor as well as simplify the layout of the interconnect structures, e.g., metal wiring the word lines and bit lines, which can reduce the fabrication complexity and improve the yield. For example, the pitches of word lines and/or bit lines can be reduced for ease of fabrication. The vertical structures of the transistors also allow the bit lines and storage units, such as capacitors, to be arranged on opposite sides of the transistors in the vertical direction (e.g., one above and on below the transistors), such that the process margin of the bit lines can be increased and the coupling capacitance between the bit lines and the storage units can be decreased.

Also, the memory cell array having vertical transistors and the peripheral circuits of the memory cell array can be formed on different wafers and bonded together in a face-to-face manner. Thus, the thermal budget of fabricating the memory cell array does not affect the fabrication of the peripheral circuits. The stacked memory cell array and peripheral circuits can also reduce the chip size compared with the side-by-side arrangement, thereby improving the array efficiency. In some implementations, more than one memory cell array is stacked over one another using bonding techniques to further increase the array efficiency. In some implementations, the word lines and bit lines are disposed close to the bonding interface due to the vertically arranged transistors, which can be coupled to the peripheral circuits through a large number (e.g., millions) of parallel bonding contacts across the bonding interface can make direct, short-distance (e.g., micron-level) electrical connections between the memory cell array and peripheral circuits to increase the throughput and input/output (I/O) speed of the memory devices.

In some implementations, the vertical transistors disclosed herein include multi-gate transistors (e.g., gate-all-around (GAA) transistors, tri-gate transistors, or double-gate transistors), which can have a larger gate control area to achieve better channel control with a smaller subthreshold swing. Since the channel is fully depleted, the leakage current of multi-gate transistors can be significantly reduced as well. Thus, using multi-gate transistors instead of planar transistors can achieve a much better speed (saturated drain current)/leakage current performance.

In some implementations, the vertical transistors disclosed herein include single-gate transistors (a.k.a. single-side gate transistors) in a mirror-symmetric arrangement with respect to adjacent transistors in the bit line direction as a result of splitting multi-gate transistors (e.g., double-gate transistors) using trench isolations extending along the word line direction. Thus, the memory cell density in the bit line direction can be significantly increased (e.g., doubled) without unduly complicating the fabrication process compared with using processes, such as self-aligned double patterning (SADP). Also, the mirror-symmetric single-gate transistors have a larger process window for word line, bit line, and transistor pitch reduction, compared to either planar transistors or multi-gate vertical transistors, for example, with dual-side or all-around gates.

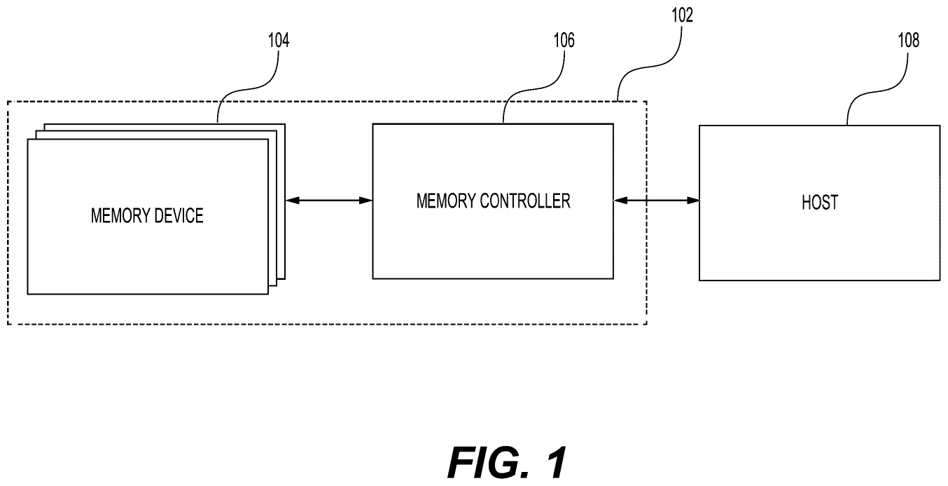

FIG. 1 illustrates a block diagram of system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive the data to or from memory devices 104.

Memory device 104 can be any memory device disclosed herein. In some implementations, memory device 104 includes an array of memory cells each including a vertical transistor, as described herein.

Memory controller 106 is coupled to memory device 104 and host 108 and is configured to control memory device 104, according to some implementations. Memory controller 106 can manage the data stored in memory device 104 and communicate with host 108. Memory controller 106 can be configured to control operations of memory device 104, such as read, write, and refresh operations. Memory controller 106 can also be configured to manage various functions with respect to the data stored or to be stored in memory device 104 including, but not limited to refresh and timing control, command/request translation, buffer and schedule, and power management. In some implementations, memory controller 106 is further configured to determine the maximum memory capacity that the computer system can use, the number of memory banks, memory type and speed, memory particle data depth and data width, and other important parameters.

Any other suitable functions may be performed by memory controller 106 as well. Memory controller 106 can communicate with an external device (e.g., host 108) according to a particular communication protocol. For example, memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

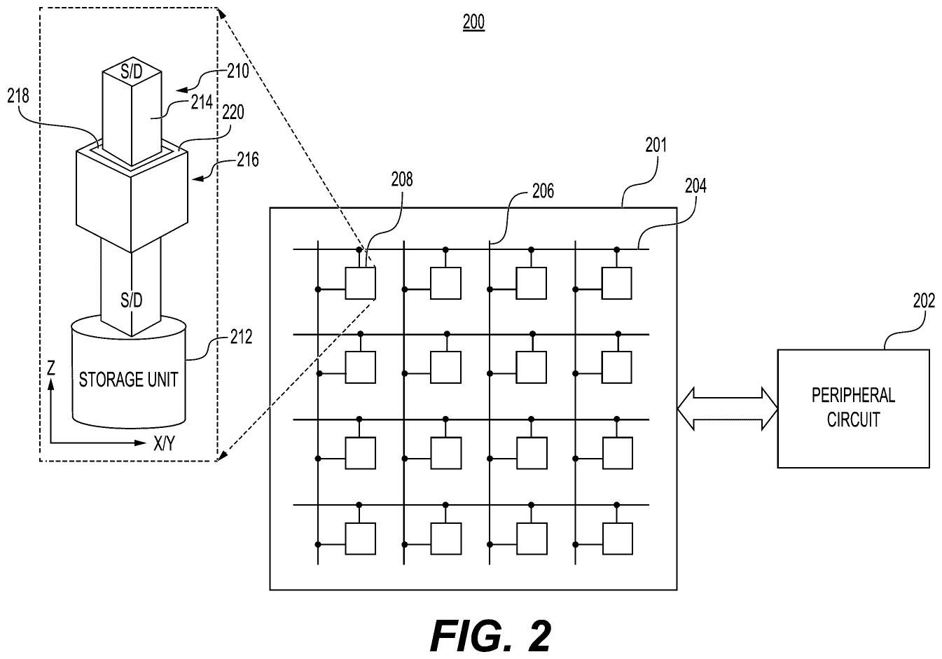

FIG. 2 illustrates a schematic diagram of a memory device 200 including peripheral circuits and an array of memory cells each having a vertical transistor, according to some aspects of the present disclosure. Memory device 200 can include a memory cell array 201 and peripheral circuits 202 coupled to memory cell array 201. Memory cell array 201 can be any suitable memory cell array in which each memory cell 208 includes a vertical transistor 210 and a storage unit 212 coupled to vertical transistor 210. In some implementations, memory cell array 201 is a DRAM cell array, and storage unit 212 is a capacitor for storing charge as the binary information stored by the respective DRAM cell. In some implementations, memory cell array 201 is a PCM cell array, and storage unit 212 is a PCM element (e.g., including chalcogenide alloys) for storing binary information of the respective PCM cell based on the different resistivities of the PCM element in the amorphous phase and the crystalline phase. In some implementations, memory cell array 201 is a FRAM cell array, and storage unit 212 is a ferroelectric capacitor for storing binary information of the respective FRAM cell based on the switch between two polarization states of ferroelectric materials under an external electric field.

As shown in FIG. 2, memory cells 208 can be arranged in a two-dimensional (2D) array having rows and columns. Memory device 200 can include word lines 204 coupling peripheral circuits 202 and memory cell array 201 for controlling the switch of vertical transistors 210 in memory cells 208 located in a row, as well as bit lines 206 coupling peripheral circuits 202 and memory cell array 201 for sending data to and/or receiving data from memory cells 208 located in a column. That is, each word line 204 is coupled to a respective row of memory cells 208, and each bit line is coupled to a respective column of memory cells 208.

Vertical transistors 210, such as vertical metal-oxide-semiconductor field-effect transistors (MOSFETs), can replace the planar transistors as the pass transistors of memory cells 208 to reduce the area occupied by the pass transistors, the coupling capacitance, as well as the interconnect routing complexity. As shown in FIG. 2, in some implementations, different from planar transistors in which the active regions are formed in the substrates, vertical transistor 210 includes a semiconductor body 214 extending vertically (in the z-direction) above the substrate (not shown). That is, semiconductor body 214 can extend above the top surface of the substrate to allow channels to be formed not only at the top surface of semiconductor body 214, but also at one or more side surfaces thereof.

As shown in FIG. 2, for example, semiconductor body 214 can have a cuboid shape to expose four sides thereof. It is understood that semiconductor body 214 may have any suitable 3D shape, such as a polyhedron shape or a cylinder shape. That is, the cross-section of semiconductor body 214 in the plan view (e.g., in the x-y plane) can have a square shape, a rectangular shape (or a trapezoidal shape), a circular (or an oval shape), or any other suitable shapes. It is understood that, for semiconductor bodies that have a circular or oval shape of their cross-sections in the plan view, the semiconductor bodies may still be considered as having multiple sides, such that the gate structures are in contact with more than one side of the semiconductor bodies. As described below with respect to the fabrication process, in some cases, semiconductor body 214 can be formed from the substrate (e.g., by etching or epitaxy) and thus, has the same semiconductor material (e.g., silicon crystalline silicon) as the substrate (e.g., a silicon substrate).

As shown in FIG. 2 example, vertical transistor 210 can also include a gate structure 216 in contact with one or more sides of semiconductor body 214, e.g., in one or more planes of the side surface(s) of the active region. In other words, the active region of vertical transistor 210, e.g., semiconductor body 214, can be at least partially surrounded by gate structure 216. Gate structure 216 can include a gate dielectric 218 over one or more sides of semiconductor body 214, e.g., in contact with four side surfaces of semiconductor body 214 as shown in FIG. 2. Gate structure 216 can also include a gate electrode 220 over and in contact with gate dielectric 218. Gate dielectric 218 can include any suitable dielectric materials, such as silicon oxide, silicon nitride, silicon oxynitride, or high-k dielectrics. For example, gate dielectric 218 may include silicon oxide, which is a form of gate oxide. Gate electrode 220 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 220 may include doped polysilicon, which is a form of a gate poly. In some implementations, gate electrode 220 includes multiple conductive layers, such as a W layer over a TiN layer. It is understood that gate electrode 220 and word line 204 may be a continuous conductive structure in some examples. In other words, gate electrode 220 may be viewed as part of word line 204 that forms gate structure 216, or word line 204 may be viewed as the extension of gate electrode 220 to be coupled to peripheral circuits 202.

As shown in FIG. 2, vertical transistor 210 can further include a pair of a source and a drain (S/D, dope regions, a.k.a., source electrode and drain electrode) formed at the two ends of semiconductor body 214 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 216 in the vertical direction (the z-direction). In other words, gate structure 216 is formed vertically between the source and drain. As a result, one or more channels (not shown) of vertical transistor 210 can be formed in semiconductor body 214 vertically between the source and drain when a gate voltage applied to gate electrode 220 of gate structure 216 is above the threshold voltage of vertical transistor 210. That is, each channel of vertical transistors 210 is also formed in the vertical direction along which semiconductor body 214 extends, according to some implementations.

In some implementations, as shown in FIG. 2, vertical transistor 210 is a multi-gate transistor. That is, gate structure 216 can be in contact with more than one side of semiconductor body 214 (e.g., four sides in FIG. 2) to form more than one gate, such that more than one channel can be formed between the source and drain in operation. That is, different from the planar transistor that includes only a single planar gate (and resulting in a single planar channel), vertical transistor 210 shown in FIG. 2 can include multiple vertical gates on multiple sides of semiconductor body 214 due to the 3D structure of semiconductor body 214 and gate structure 216 that surrounds the multiple sides of semiconductor body 214. As a result, compared with planar transistors, vertical transistor 210 shown in FIG. 2 can have a larger gate control area to achieve better channel control with a smaller subthreshold swing. Since the channel is fully depleted, the leakage current (Ioff) of vertical transistor 210 can be significantly reduced a well. In various examples, the multi-gate vertical transistors can include double-gate vertical transistors (e.g., dual-side gate vertical transistors), tri-gate vertical transistors (e.g., tri-side gate vertical transistors), and GAA vertical transistors.

It is understood that although vertical transistor 210 is shown as a multi-gate transistor in FIG. 2, the vertical transistors disclosed herein may also include single-gate transistors. That is, gate structure 216 may be in contact with a single side of semiconductor body 214, for example, for the purpose of increasing the transistor and memory cell density. It is also understood that although gate dielectric 218 is shown as being separate (a separate structure) from other gate dielectrics of adjacent vertical transistors (not shown), gate dielectric 218 may be part of a continuous dielectric layer having multiple gate dielectrics of vertical transistors.

In planar transistors and some lateral multiple-gate transistors (e.g., FinFET), the active regions, such as semiconductor bodies (e.g., Fins), extend laterally (in the x-y plane), and the source and the drain are disposed at different locations in the same lateral plane (the x-y plane). In contrast, in vertical transistor 210, semiconductor body 214 extends vertically (in the z-direction), and the source and the drain are disposed in the different lateral planes, according to some implementations. In some implementations, the source and the drain are formed at two ends of semiconductor body 214 in the vertical direction (the z-direction), respectively, thereby being overlapped in the plan view. As a result, the area (in the x-y plane) occupied by vertical transistor 210 can be reduced compared with planar transistors and lateral multiple-gate transistors. Also, the metal wiring coupled to vertical transistors 210 can be simplified as well since the interconnects can be routed in different planes. For example, bit lines 206 and storage units 212 may be formed on opposite sides of vertical transistor 210. In one example, bit line 206 may be coupled to the source or the drain at the upper end of semiconductor body 214, while storage unit 212 may be coupled to the other source or the drain at the lower end of semiconductor body 214.

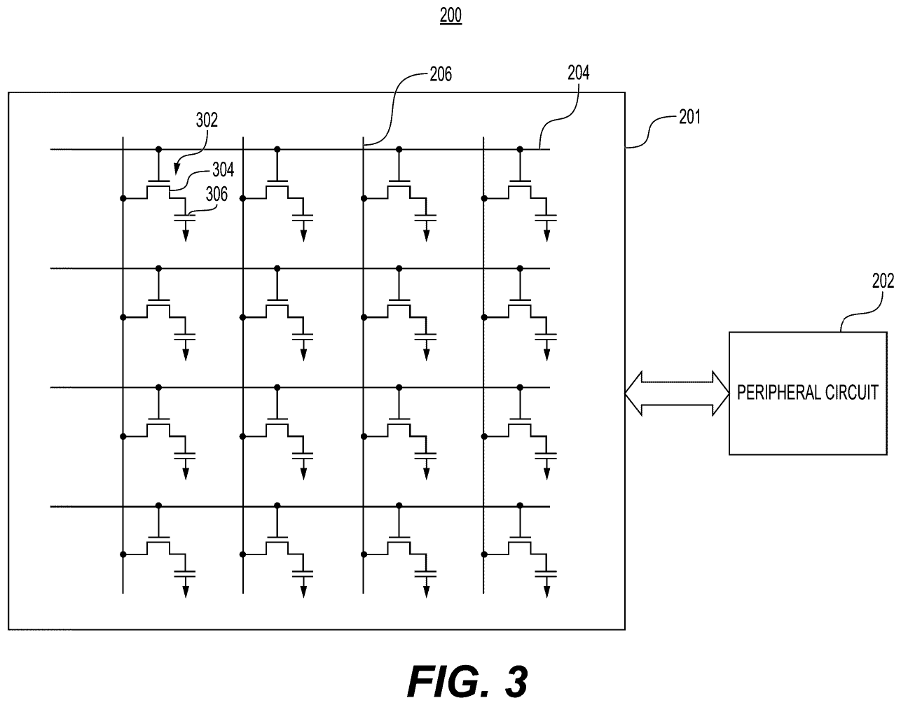

As shown in FIG. 2, storage unit 212 can be coupled to the source or the drain of vertical transistor 210. Storage unit 212 can include any devices that are capable of storing binary data (e.g., 0 and 1), including but not limited to, capacitors for DRAM cells and FRAM cells, and PCM elements for PCM cells. In some implementations, vertical transistor 210 controls the selection and/or the state switch of the respective storage unit 212 coupled to vertical transistor 210. In some implementations, as shown in FIG. 3, each memory cell 208 is a DRAM cell 302 including a transistor 304 (e.g., implementing using vertical transistors 210 in FIG. 2) and a capacitor 306 (e.g., an example of storage unit 212 in FIG. 2). The gate of transistor 304 (e.g., corresponding to gate electrode 220) may be coupled to word line 204, one of the source and the drain of transistor 304 may be coupled to bit line 206, the other one of the source and the drain of transistor 304 may be coupled to one electrode of capacitor 306, and the other electrode of capacitor 306 may be coupled to the ground.

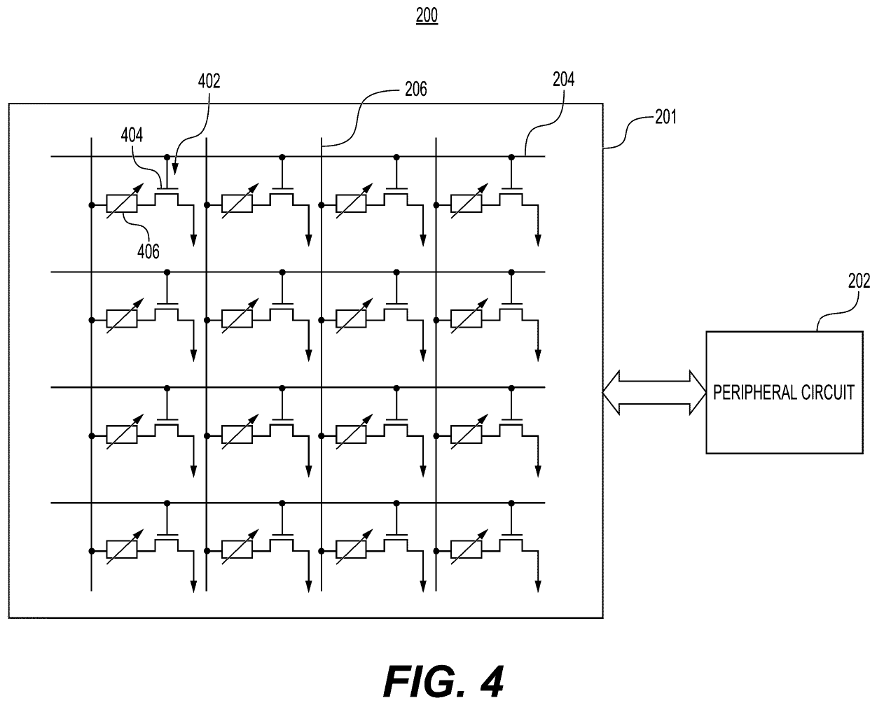

In some implementations, as shown in FIG. 4, each memory cell 208 is a PCM cell 402 including a transistor 404 (e.g., implementing using vertical transistors 210 in FIG. 2) and a PCM element 406 (e.g., an example of storage unit 212 in FIG. 2). The gate of transistor 404 (e.g., corresponding to gate electrode 220) may be coupled to word line 204, one of the source and the drain of transistor 404 may be coupled to the ground, the other one of the source and the drain of transistor 404 may be coupled to one electrode of PCM element 406, and the other electrode of PCM element 406 may be coupled to bit line 206.

Peripheral circuits 202 can be coupled to memory cell array 201 through bit lines 206, word lines 204, and any other suitable metal wirings. As described above, peripheral circuits 202 can include any suitable circuits for facilitating the operations of memory cell array 201 by applying and sensing voltage signals and/or current signals through word lines 204 and bit lines 206 to and from each memory cell 208. For example, peripheral circuits 202 can include various types of peripheral circuits formed using CMOS technologies.

### II. Forming Memory Devices by Employment of Etch-Stop Layers

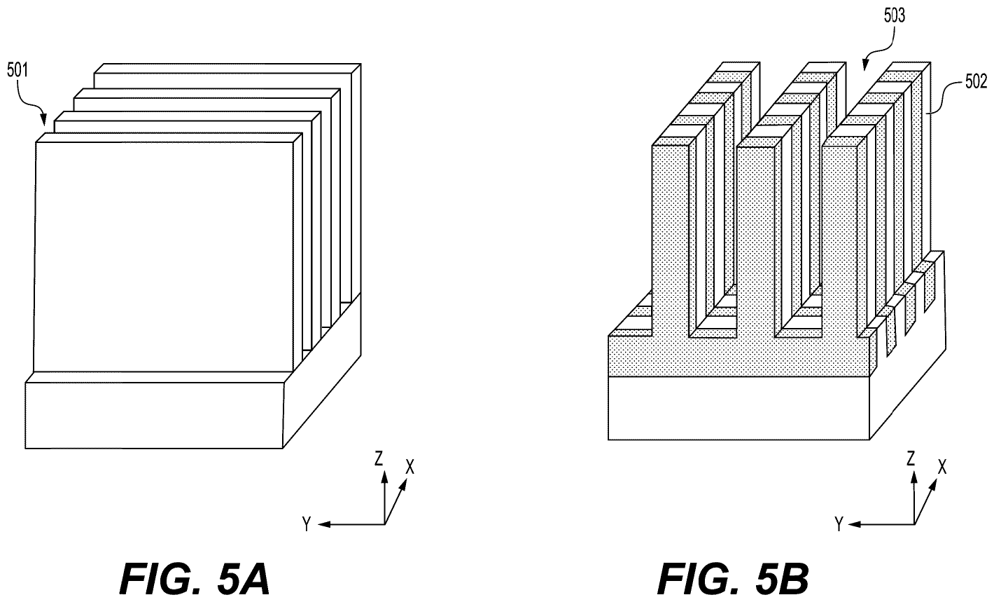

FIGS. 5A-5B illustrate a memory device fabrication process where semiconductor bodies 502 of vertical transistors are formed without the employment of etch-stop layers. In FIG. 5A, multiple first trenches (isolation trenches) 501 can be formed along the bit line direction (y-direction) in a silicon substrate. For example, a first lithography process and a first etching process can be performed in the substrate to form isolation trenches 501. An insulating material, such as silicon oxide, can be filled in the isolation trenches to form trench isolations. In FIG. 5B, multiple second trenches (referred to as word line trenches or gate trenches) 503 can be formed along the word line direction (x-direction), crossing the trench isolations. For example, a second lithography patterning process and a second etching process can be performed to for the word line trenches 503. As a result, the multiple semiconductor bodies 502 surrounded by the trench isolations and the word line trenches 503 can be formed.

In the fabrication process of FIGS. 5A-5B, there are no etch stop layers formed and used for the first etching process in the y-direction and the second etching process in the x-direction. Due to the high aspect ratio of the first trenches and the second trenches, it is difficult to control the bottom profile and the etch depth uniformity of these trenches. Also, in some implementations, in a later fabrication stage, a backside silicon recess process is performed to remove silicon and form recesses below the semiconductor bodies 502 and between the trench isolations along the bit line direction. Source/Drain region doping and bit line deposition can be performed in the recesses. Similarly, for forming these recesses, when no etch-stop layer is employed, it is difficult to control the recess uniformity.

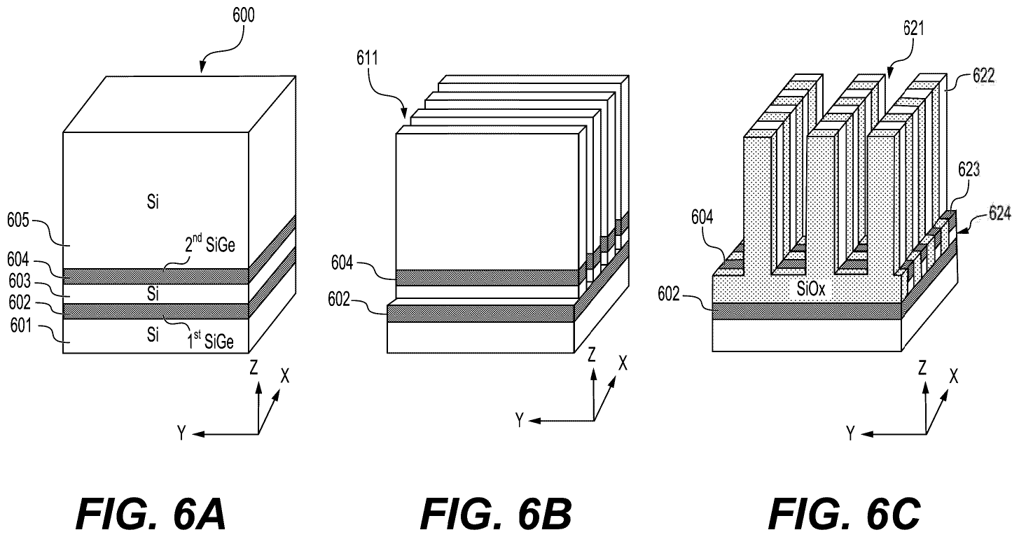

FIGS. 6A, 68, and 6C illustrate a memory device fabrication process where etch-stop layers are employed to improve the bottom profile uniformity and the etch depth uniformity of the isolation trenches and the word line trenches as well as the backside bit line silicon recesses.

In FIG. 6A, a layer stack 600 can be formed in various ways. As an example, a semiconductor substrate 601 can first be provided. Subsequently, a first semiconductor layer 602, a second semiconductor layer 603, a third semiconductor layer 604, and a fourth semiconductor layer 605 can be sequentially formed. In some implementations, the semiconductor substrate 601 can be a crystalline silicon substrate, and the multiple layers 602-605 can be epitaxially grown. In some implementations, other formation methods may be employed to form the layer stack 600. In some implementations, the two etch-stop layers are silicon germanium (SiGe) epitaxial layers, and the two semiconductor layers 603 and 605 are silicon epitaxial layers.

In FIG. 6B, isolation trenches 611 can be formed along the bit line direction. As shown, the first semiconductor layer 602 can be employed as an etch-stop layer for the etch of the isolation trenches 611. The resulting isolation trenches 611 cross downwards the fourth semiconductor layer 605, the third semiconductor layer 604, and the second semiconductor layer 603, and arrive at or enter the first semiconductor layer 602. The isolation trenches 611 can then be filled with an insulating material, such as silicon dioxide, to form trench isolations.

In FIG. 6C, word line trenches 621 can be formed along the word line direction. As shown, the third semiconductor layer 604 can be employed as an etch-stop layer for the etching of the word line trenches 621. The resulting word line trenches 621 cross downwards the fourth semiconductor layer 605 (the remaining portions sandwiched between neighboring trench isolations) and the trench isolations and arrive at or enter the third semiconductor layer 604. Vertically positioned semiconductor bodies 622 are accordingly formed.

Also shown in FIG. 6C, remaining portions 623 of the third semiconductor layer 604 are positioned below the semiconductor bodies 622, sandwiched between neighboring trench isolations, and above the second semiconductor layer 603. In a later stage of the fabrication process, remaining portions 623 can serve as part of a bit line structure. A remaining portion 623 (possible with additional doping) can thus referred to as a bit line SiGe structure when SiGe is used in the third semiconductor layer 604.

Remaining portions 624 of the second semiconductor layer 603 are positioned between the remaining portions 623 and the first semiconductor layer 602 and sandwiched between neighboring trench isolations. In a later stage of the fabrication process, the substrate 601 and the first semiconductor layer 602 can be removed. Subsequently, remaining portions 624 can be removed (silicon recess process), forming recesses (referred to as bit line recesses) in the spaces of remaining portions 624. Bit line metals can be deposited in the bit line recesses and adjacent to the bottom surfaces of the bit line SiGe structures 623. In the silicon recess process, the third semiconductor layer 604 (the bit line SiGe structures 623) can be employed as an etch-stop layer for the etch of the remaining portions 624.

As described with reference to FIGS. 6A-6C, the stack of epitaxially-grown Si—SiGe layers over a silicon substrate can be introduced. The SiGe epitaxial layers can serve as etch-stop layers for forming the isolation trenches, the word line trenches, and the bit line silicon recesses, improving the etch profile and etch depth uniformity.

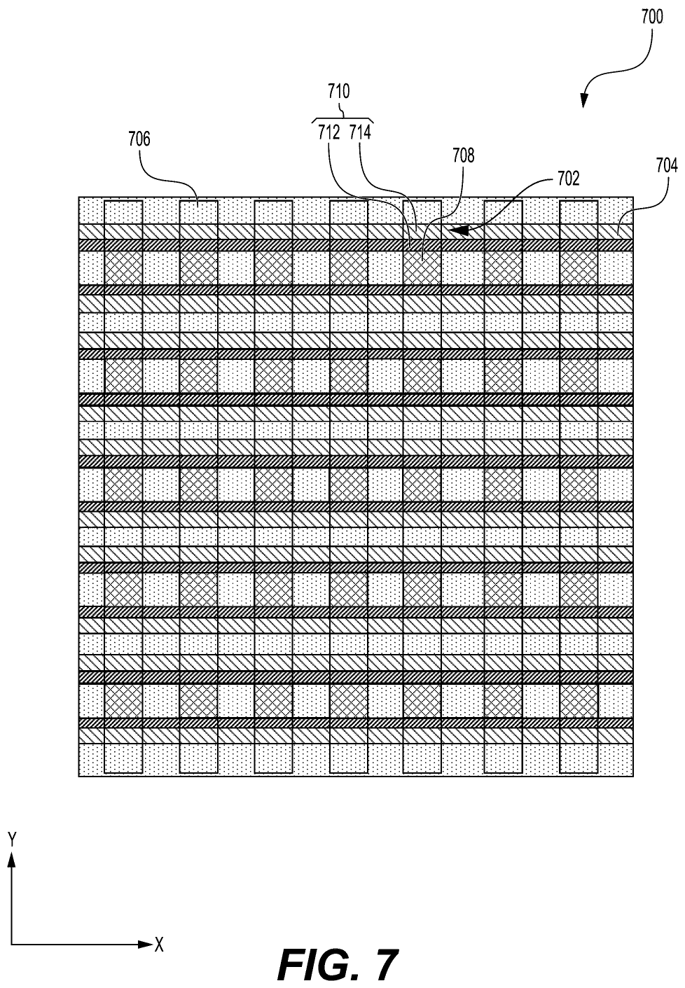

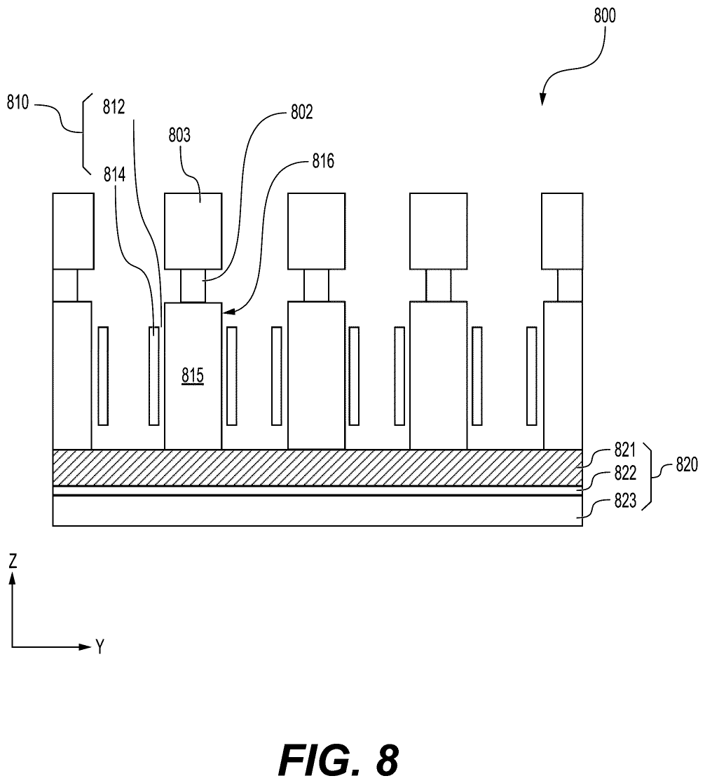

Memory devices that are fabricated by employing the above-introduced etch-stop layers are described with references to FIGS. 7-8. FIG. 7 illustrates a plan view of an array of memory cells 702 each including a vertical transistor in a memory device 700, according to some aspects of the present disclosure. As shown in FIG. 7, memory device 700 can include a plurality of word lines 704 each extending in a first lateral direction (the x-direction, referred to as the word line direction). Memory device 700 can also include a plurality of bit lines 706 each extending in a second lateral direction perpendicular to the first lateral direction (the y-direction, referred to as the bit line direction). The bit line 706 can include the remaining portion 623 of the third semiconductor layer 604 (the bit line SiGe structure 623) in the example of FIGS. 6A-6C. It is understood that FIG. 7 does not illustrate a cross-section of memory device 700 in the same lateral plane, and word lines 704 and bit lines 706 may be formed in different lateral planes for ease of routing.

Memory cells 702 can be formed at the intersections of word lines 704 and bit lines 706. In some implementations, each memory cell 702 includes a vertical transistor (e.g., vertical transistor 210 in FIG. 2) having a semiconductor body 708 and a gate structure 710. Semiconductor body 708 can extend in a substrate in the vertical direction (the z-direction, not shown) perpendicular to the first and second lateral directions. The vertical transistor can be a dual-gate transistor in which two gate structures 710 are in contact with opposite sides (e.g., two of four sides in FIG. 7) of semiconductor body 708 (the active region in which channels are formed). As shown in FIG. 7, each of the two gate structures 710 abuts one side of semiconductor body 708 (having a rectangle or square-shaped cross-section) in the bit line direction (the y-direction) in the plan view. Gate structure 710 does not surround and contact other two sides of semiconductor body 708 in the word line direction, according to some implementations.

Gate structure 710 can include a gate dielectric 712 abuts one side of semiconductor body 708 in the plan view, and a gate electrode 714 in contact with gate dielectric 712. In some implementations, gate dielectric 712 is laterally between gate electrode 714 and semiconductor body 708 in the bit line direction (the y-direction). Gate electrode 714 may be part of word line 704, and word line 704 may be an extension of gate electrode 714. That is, gate electrodes 714 of adjacent vertical transistors in the word line direction (the x-direction) are continuous, e.g., parts of a continuous conductive layer having gate electrodes 714. In some implementations, gate structures 710 of a row of the vertical transistors are continuous in the x-direction, as a shown in FIG. 7.

In some other implementations, semiconductor bodies 708 can be split into two pieces using a trench isolation extending in the word line direction (the x-direction) and in parallel with word lines 704. The trench isolations and word lines 704 can be disposed in an interleaved manner in the bit line direction. For example, trench isolation is formed in the middle of the semiconductor pillars (not shown). As a result, the pair of semiconductor bodies are mirror-symmetric to one another with respect to trench isolation. The pair of single-gate vertical transistors corresponding to the pair of semiconductor bodies are mirror-symmetric on one another with respect to trench isolation. The respective gate structures 710 are mirror-symmetric to one another with respect to trench isolation as well.

By splitting the double-gate vertical transistors into single-gate vertical transistors using trench isolations, the number of memory cells (and the cell density) in the bit line direction can be doubled compared to double-gate vertical transistors without unduly complexing the fabrication process (e.g., compared with using SADP process).

FIG. 8 illustrates a side view of a cross-section of a memory device 800 made by employing the etch-stop layers introduced above, according to some aspects of the present disclosure. The memory device 800 may be one example of memory device 700 including dual-gate vertical transistors. It is understood that FIG. 8 is for illustrative purposes only and may not necessarily reflect the actual device structure size or scale in practice. Memory device 800 can include an array of memory cells (e.g., DRAM cells). The cross-section of memory device 800 can be made in a y-z plane cutting through a row of memory cells and a bit line under thereof. As shown, each memory cell in the row can include a vertical transistor 816 and a storage unit 803 (for example, including a capacitor) coupled to the vertical transistor 816. The row of memory cells stands on the bit line 820.

In some implementations, the bit line 820 includes a semiconductor line 821 (or semiconductor layer 821), a contact line 822 (a first connection layer 822), and a metal line 823 (a second connection layer 823). The semiconductor line 821 can be similar to the remaining portions (or the bit line SiGe structure) 623 in FIG. 6C, resulting from an etch-stop layer in a stack of Si—SiGe layers. For example, semiconductor line 821 can include SiGe. Semiconductor line 821 can be an epitaxially-grown semiconductor layer (or semiconductor epitaxial layer). For example, semiconductor line 821 can be an epitaxially-grown SiGe layer (or SiGe epitaxial layer), as opposed to a SiGe layer formed by implanting Ge into a silicon layer. Various growth techniques can be employed for forming a SiGe semiconductor line 821, such as molecular-beam epitaxy (MBE), low-pressure chemical vapour deposition (LPCVD) and ultra-high vacuum chemical vapour deposition (UHV-CVD).

In some implementations, the Ge concentration in the SiGe semiconductor line 821 is optimized to obtain a certain concentration profile in the vertical direction. For example, the Ge concentration can be controlled to be at a lower level near an interface between a SiGe layer and an adjacent lower or upper silicon layer, compared with the locations far from the interface. In this way, the SiGe crystal lattice can closely match the lattice constant of the silicon layer, reducing strain and defects as well as contact resistance at the Si—SiGe interface and thus improving the electrical and structural properties of a device. At the locations far from the interface, the Ge concentration can be controlled to be at a desired level to achieve a desired electrical and structural property.

Accordingly, in some implementations, a concentration of Ge decreases upwards in the vertical direction at an upper side of the SiGe semiconductor line 821. In some implementations, a first concentration of Ge at a first position is greater than a second concentration of Ge at a second position, and the first position is below the second position along the vertical direction at an upper side of the SiGe semiconductor line 821. In some implementations, a concentration of Ge decreases upwards from 20% to 5% in the vertical direction at an upper side of the SiGe semiconductor line 821. In some implementations, a first concentration of Ge at a first position is in a range of 25%-15%, and a second concentration of Ge at a second position is in a range of 10%-2%, and the first position being below the second position in the vertical direction at an upper side of the SiGe semiconductor line 821.

In some implementations, the Ge concentration near the upper surface and the lower surface of the SiGe semiconductor line 821 is lower, while the Ge concentration in the middle of the SiGe semiconductor line 821 is higher. Consequently, in the top-to-bottom direction, the Ge concentration increases initially, then decreases in the SiGe semiconductor line 821. In some implementations, in the top-to-bottom direction, the Ge concentration increases initially, then maintains the concentration level in the SiGe semiconductor line 821. In some implementations, in the top-to-bottom direction, the Ge concentration increases continuously until the lower surface of the SiGe semiconductor line 821.

In some implementations, silicon and germanium are miscible over the full range of compositions and hence can be combined to form Si₁₋ₓGeₓ alloys with the germanium content, x, ranging from 0 to 1 (0-100%). Si₁₋ₓGeₓ has a diamondlike lattice structure. When a Si₁₋ₓGeₓ layer is grown on a silicon substrate, the lattice mismatch at the interface between the Si₁₋ₓGeₓ and the silicon is accommodated. This can either be done by compression of the Si₁₋ₓGeₓ layer so that it fits to the silicon lattice or by the creation of misfit dislocations at the interface. In the former case, the Si₁₋ₓGeₓ layer adopts the silicon lattice spacing in the plane of the growth and hence the normally cubic Si₁₋ₓGeₓ crystal is distorted. When Si₁₋ₓGeₓ growth occurs in this way, the Si₁₋ₓGeₓ layer is under compressive strain and the layer is described as pseudomorphic. In the second case, the Si₁₋ₓGeₓ layer is unstrained, or relaxed, and the lattice mismatch at the interface is accommodated by the formation of misfit dislocations. These misfit dislocations generally lie in the plane of the interface, but dislocations can also thread vertically through the Si₁₋ₓGeₓ layer.

In some implementations, the semiconductor line 821 can be doped with N-type dopants (e.g., P or As) or P-type dopants (e.g., B or Ga), at a desired doping level or doping profile. For example, semiconductor line 821 can be a doped SiGe line. The doped semiconductor line 821 can function as a source/drain region for the vertical transistors above thereof. In some implementations, a SiGe layer formed by implanting Ge into a silicon layer (optionally followed by annealing) may be used in place of the SiGe epitaxial layer in the semiconductor line 821.

In some implementations, the contact line 822 covers the semiconductor line 821. The contact line 822 (or connection layer 822) can be an ohmic contact, such as a metal silicide contact, as opposed to a Schottky contact. For example, the contact line 822 may include metal silicides, such as NiSi, TiSi, WSi, CoSi, CuSi, AiSi, or any other suitable metal silicides having higher conductivities than doped silicon. In some implementations, the metal line 823 can include W, Co, Cu, Al, or any other suitable metals having higher conductivities than doped silicon. In some implementations, the contact line 822 may be omitted, and the metal line 823 is in direct contact to the semiconductor line 821. In some implementations, the contact line 822 and the metal line 823 do not exist and are not configured for the memory device 800. The semiconductor line 821 functions as a bit line for connecting the above-standing vertical transistors. In some implementations, an additional semiconductor is positioned below and in contact with the semiconductor line 821. The two semiconductor lines together function as a bit line.

Vertical transistor 816 can be a MOSFET used to switch a respective memory cell. In some implementations, vertical transistor 816 includes a semiconductor body 815 (the active region in which a channel can form) extending vertically (in the z-direction), and two gate structure 810 in contact with each opposite side of semiconductor body 815 in the bit line direction (they-direction). Semiconductor body 815 can have a cuboid shape or a cylinder shape, and gate structure 810 can abut one side of semiconductor body 815 in the plan view, for example, as shown in FIG. 8. Gate structure 810 includes a gate electrode 814 and a gate dielectric 812 laterally between gate electrode 814 and semiconductor body 815 in the bit line direction, according to some implementations. In some implementations, gate dielectric 812 abuts one side of semiconductor body 815, and gate electrode 814 abuts gate dielectric 812.

As shown in FIG. 8, in some implementations, semiconductor body 815 has two ends (the upper end and lower end) in the vertical direction (the z-direction), and at least one end (e.g., the lower end in FIG. 8) extends beyond gate dielectric 812 in the vertical direction (the z-direction). In some implementations, one end (e.g., the upper end in FIG. 8) of semiconductor body 815 is flush with the respective end (e.g., the upper end in FIG. 8) of gate dielectric 812. In some implementations, both ends (the upper end and lower end) of semiconductor body 815 extend beyond gate electrode 814, respectively, in the vertical direction (the z-direction). That is, semiconductor body 815 can have a larger vertical dimension (e.g., the depth) than that of gate electrode 814 (e.g., in the z-direction), and neither the upper end nor the lower end of semiconductor body 815 is flush with the respective end of gate electrode 814. Thus, short circuits between bit lines 820 and word lines/gate electrodes 814 or between word lines/gate electrodes 814 and storage units 803 can be avoided.

Vertical transistor 816 can further include a source and a drain (their locations may be interchangeable) disposed at the two ends (the upper end and lower end) of semiconductor body 815, respectively, in the vertical direction (the z-direction). In some implementations, one of source and drain (e.g., at the upper end in FIG. 8) is coupled to storage unit 803, and the other one of source and drain (e.g., at the lower end in FIG. 8) is coupled to bit line 820. That is, vertical transistor 816 can have a first terminal in the positive z-direction and a second terminal opposite the first terminal in the negative z-direction, as shown in FIG. 8. In some implementations, bit line 820 is coupled to the second terminal of vertical transistor 816.

In some implementations, semiconductor body 815 includes semiconductor materials, such as single crystalline silicon, polysilicon, amorphous silicon, Ge, any other semiconductor materials, or any combinations thereof. In one example, semiconductor body 815 may include single crystalline silicon. Source and drain can be doped with N-type dopants (e.g., P or As) or P-type dopants (e.g., B or Ga) at a desired doping level or doping profile. In some implementations, a silicide layer, such as a metal silicide layer, is formed between source/drain of vertical transistor 816 and bit line 820 (if implemented as a metal line) as the bit line contact or between source/drain of vertical transistor 816 and the first electrode of storage unit 803 to reduce the contact resistance.

In some implementations, gate dielectric 812 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 814 includes conductive materials including, but not limited to W, Co, Cu, Al, TiN, TaN, polysilicon, silicides, or any combination thereof. In some implementations, gate electrode 814 includes multiple conductive layers, such as a W layer over a TiN layer. In one example, gate structure 810 may be a “gate oxide/gate poly” gate in which gate dielectric 812 includes silicon oxide and gate electrode 814 includes doped polysilicon. In another example, gate structure 810 may be an HKMG in which gate dielectric 812 includes a high-k dielectric and gate electrode 814 includes a metal.

As described above, since gate electrode 814 may be part of a word line or extend in the word line direction (e.g., the x-direction in FIG. 18) as a word line, as shown in FIG. 18, memory device 800 can also include a plurality of word lines (referred to as 814) each extending in the word line direction (the x-direction). Each word line 814 can be coupled to a row of memory cells. That is, bit line 820 and word line 814 can extend in two perpendicular lateral directions, and semiconductor body 815 of vertical transistor 816 can extend in the vertical direction perpendicular to the two lateral directions in which bit line 820 and word line 814 extend. Word lines 814 are in contact with word line contacts (not shown), according to some implementations. In some implementations, word lines 814 include conductive materials including, but not limited to W, Co, Cu, Al, TiN, TaN, polysilicon, silicides, or any combination thereof. In some implementations, word line 814 includes multiple conductive layers, such as a W layer over a TiN layer.

As shown in FIG. 8, in some implementations, storage unit 803 includes a first electrode above and coupled to source or drain of vertical transistor 816, e.g., the upper end of semiconductor body 815, via a storage unit contact 802. In some implementations, storage unit contact 802 is an ohmic contact, such as a metal silicide contact, as opposed to a Schottky contact. For example, storage unit 803 can be a capacitor having a capacitor dielectric above and in contact with the first electrode, and a second electrode above and in contact with the capacitor dielectric. That is, storage unit 803 can be a vertical capacitor in which the electrodes and capacitor dielectric are stacked vertically (in the z-direction), and the capacitor dielectric can be sandwiched between the electrodes. In some implementations, each first electrode is coupled to source or drain of a respective vertical transistor 816 in the same memory cell, while all second electrodes are coupled to a common plate coupled to the ground, e.g., a common ground. Storage unit 803 can have a first end in the negative z-direction and a second end opposite the first end in the positive z-direction, as shown in FIG. 8.

It is understood that the structure and configuration of storage unit 803 are not limited to the example in FIG. 8 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, storage unit 803 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 8, vertical transistor 816 extends vertically through and contacts word lines 814, source or drain of vertical transistor 816 at the lower end thereof is in contact with bit line 820, and source or drain of vertical transistor 816 at the upper end thereof is coupled to storage unit 803, according to some implementations. That is, bit line 820 and storage unit 803 can be disposed in different planes in the vertical direction and coupled to opposite ends of vertical transistor 816 of memory cell in the vertical direction due to the vertical arrangement of vertical transistor 816. In some implementations, bit line 820 and storage unit 803 are disposed on opposite sides of vertical transistor 816 in the vertical direction, which simplifies the routing of bit lines 820 and reduces the coupling capacitance between bit lines 820 and storage units 803 compared with memory cells in which the bit lines and capacitors are disposed on the same side of the planar transistors.

III. Fabrication Process of Memory Device with Employment of Etch-Stop Layers

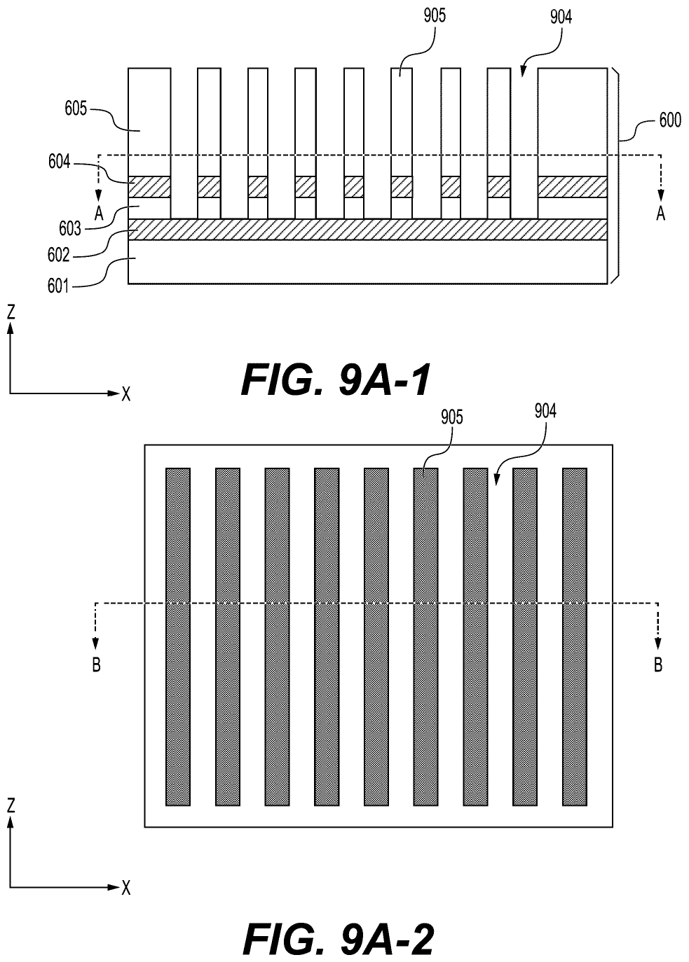

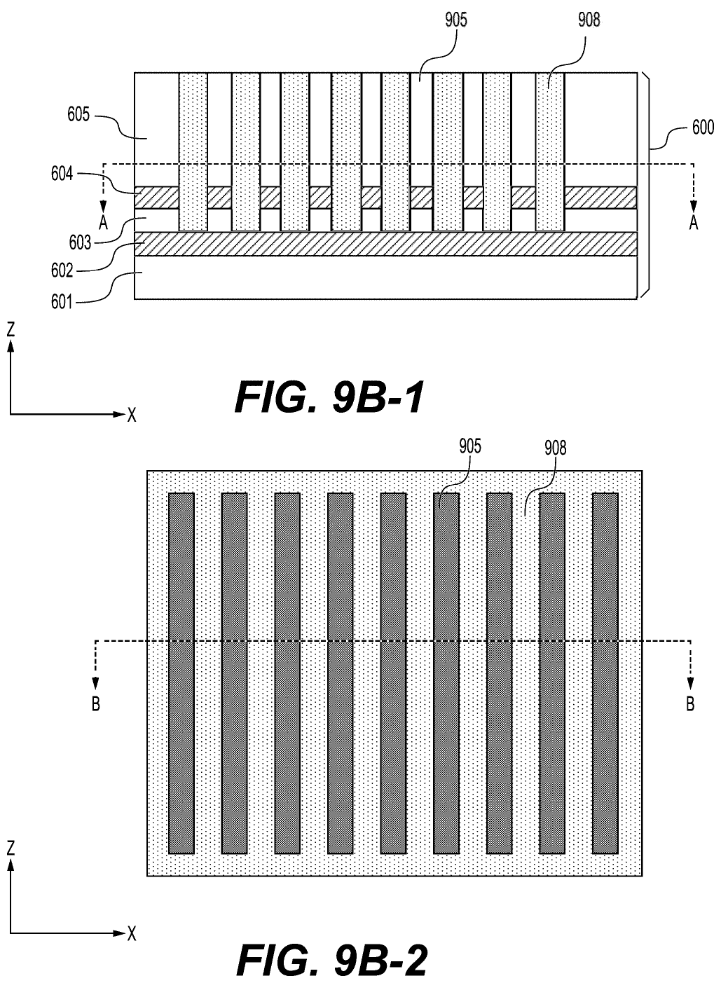

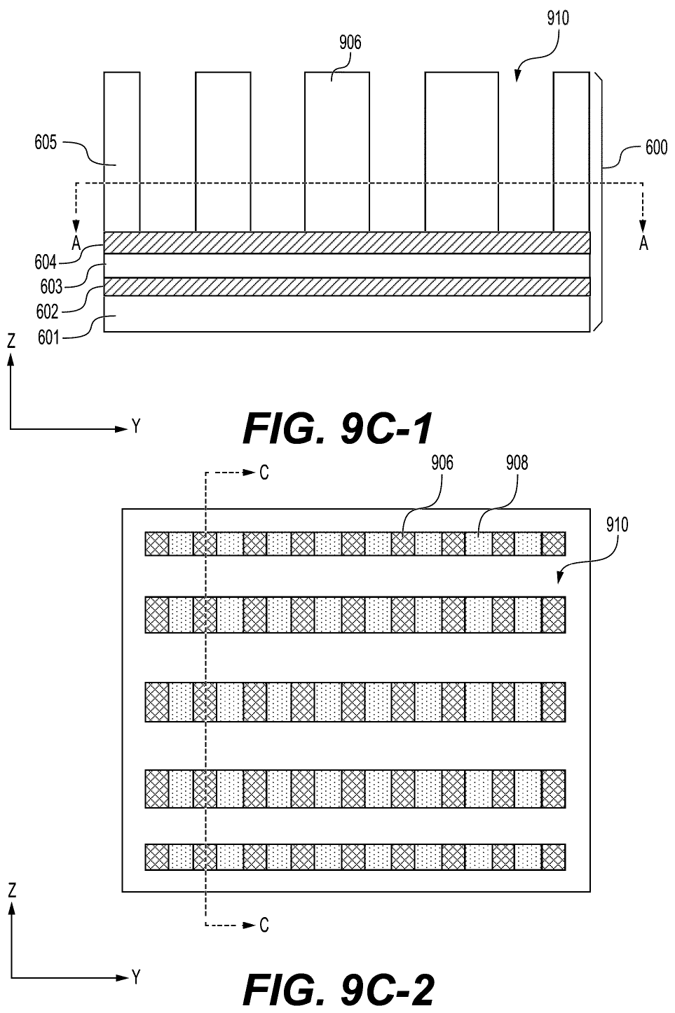

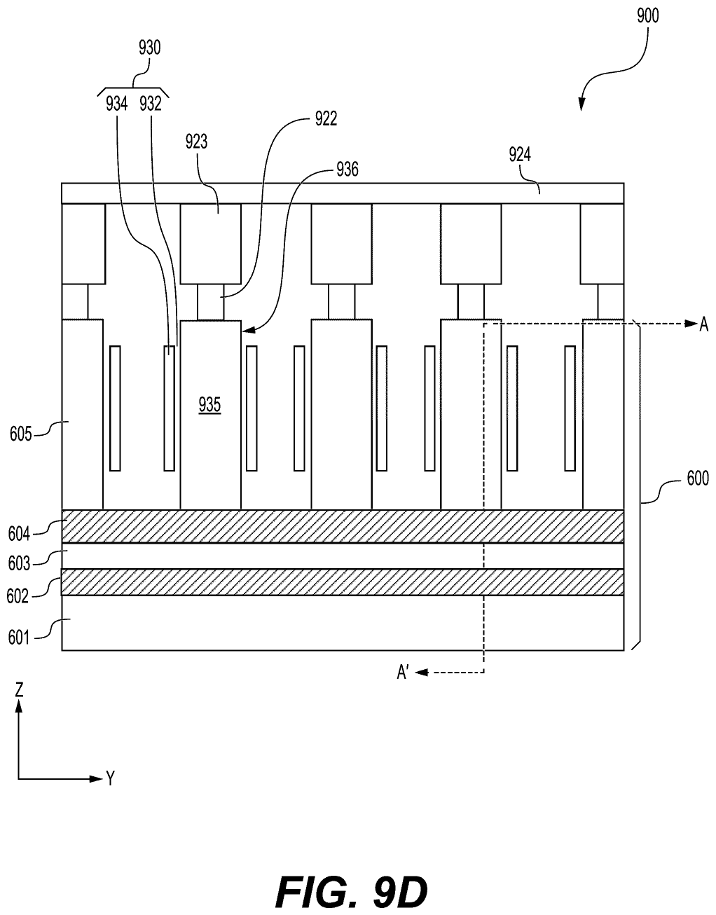

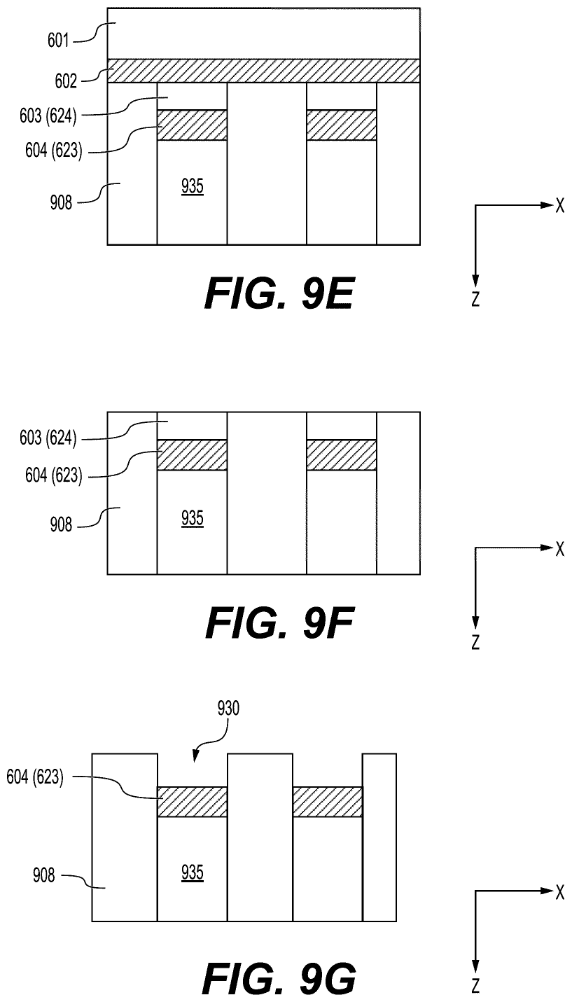

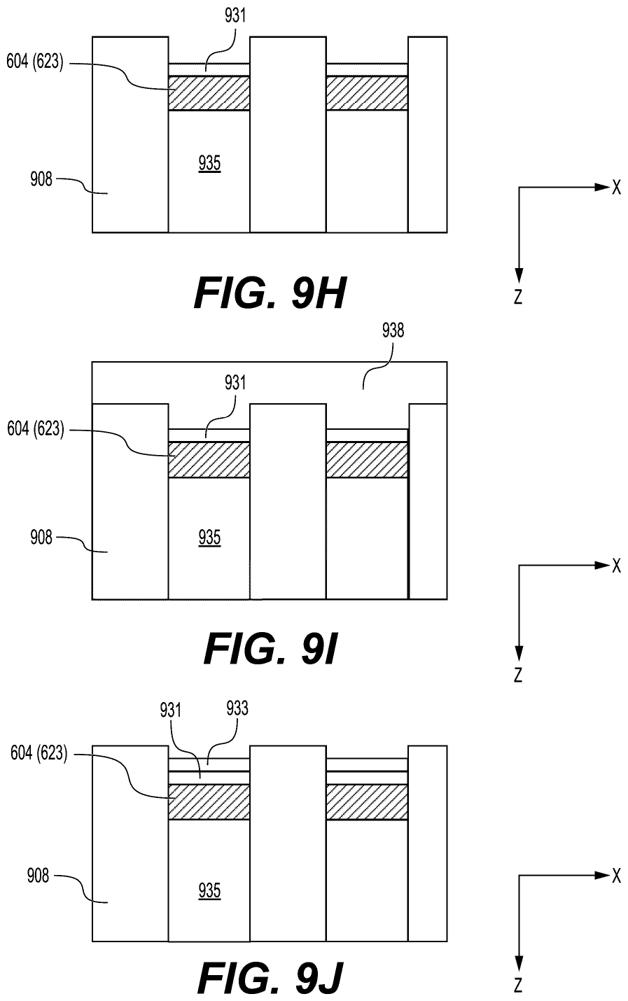

FIGS. 9A-1/9A-2/9B-1/9B-2/9C-1/9C-2 and 9D-9J illustrate a fabrication process for forming a memory device (such as the memory device 700 or 800) by using several etch-stop layers, according to some aspects of the present disclosure. The memory device can include an array of memory cells each including a vertical transistor and a storage unit coupled to the vertical transistor.

In FIG. 9A-1 and FIG. 9A-2, a plurality of parallel trenches 904 are formed in the y-direction (e.g., the bit line direction) to form a plurality of parallel semiconductor walls 905 in the y-direction in a stack of semiconductor layers (films), such as the stack 600 in FIG. 6A.

Before the processing steps in FIG. 9A-1 and FIG. 9A-2, the stack 600 can first be formed. As shown, the stack 600 includes the semiconductor substrate 601, the first semiconductor layer 602, the second semiconductor layer 603, the third semiconductor layer 604, and the fourth semiconductor layer 605. For example, the process of forming the stack 600 can include epitaxially growing the first semiconductor layer 602 over the semiconductor substrate 601, the second semiconductor layer 603 over the first semiconductor layer 602, the third semiconductor layer 604 over the second semiconductor layer 603, and the fourth semiconductor layer 60 over the third semiconductor layer 604. The semiconductor substrate 601 can include silicon (e.g., single crystalline silicon, c-Si), silicon germanium (SiGe), gallium arsenide (GaAs), germanium (Ge), silicon-on-insulator (SOI), or any other suitable materials.

In some implementations, the first semiconductor layer 602 and/or the third semiconductor layer 604 include SiGe that is epitaxially grown over the lower-layer (the semiconductor substrate 601 or the second semiconductor layer 603). Various growth techniques can be employed for forming a SiGe epitaxial layer, such as molecular-beam epitaxy (MBE), low-pressure chemical vapour deposition (LPCVD) and ultra-high vacuum chemical vapour deposition (UHV-CVD). In some implementations, the first semiconductor layer 602 and/or the third semiconductor layer 604 include SiGe that is formed by implanting Ge into a silicon layer. For example, Ge pre-amorphization implantation (PAI) with Ge ions at certain energies can be performed to form SiGe. An annealing process may be performed after the Ge implantation.

In some implementations, the concentration of Ge in the SiGe layer (the first semiconductor layer 602 and/or the third semiconductor layer 604) decreases upwards at an upper side of the SiGe layer adjacent to the upper semiconductor layer 603 or 605. For example, the concentration of Ge decreases upwards from 20% to 5%.

In some implementations, the Ge concentration near the upper surface and the lower surface of the SiGe layers 602 and/or 604 is lower, while the Ge concentration in the middle of the SiGe layers 602 and/or 604 is higher. Consequently, in the top-to-bottom direction, the Ge concentration increases initially, then decreases in the SiGe layers 602 and/or 604. In some implementations, in the top-to-bottom direction, the Ge concentration increases initially, then maintains the concentration level in the SiGe layers 602 and/or 604. In some implementations, in the top-to-bottom direction, the Ge concentration increases continuously until the lower surface of the SiGe layers 602 and/or 604.

In some implementations, the first semiconductor layer 602 and/or the third semiconductor layer 604 is doped with N-type dopants (e.g., P or As) or P-type dopants (e.g., B or Ga) at a desired doping level or doping profile. For example, the first semiconductor layer 602 and/or the third semiconductor layer 604 can be epitaxially grown with in situ doping. For example, the first semiconductor layer 602 and/or the third semiconductor layer 604 can be doped by performing an implantation process and/or a thermal diffusion process.

In some implementations, the semiconductor layer 603 and/or 605 can include epitaxially-grown silicon or other epitaxially-grown semiconductor materials. Generally, high etch selectivities between the layers 602 and 603, between the layers 605 and 604, and between the layers 603 and 604 are desired.

To form trenches 904, a lithography process is performed to pattern trenches 904 and semiconductor walls 905 using an etch mask (e.g., a photoresist mask and/or a hard mask), for example, based on the design of bit lines. One or more dry etching and/or wet etching processes, such as reactive ion etch (RIE), are performed to etch trenches 904 in the stack 600. The first semiconductor layer 602 is used to ensure the uniformity of the etch depth and the bottom profile of the trenches 904. Semiconductor wall 905 extends vertically and through the second etch stop layer 604 in the stack 600 and stands on top of the first semiconductor layer 602. The upper surface of the first semiconductor layer 602 forms the bottoms of the trenches 904.

FIG. 9A-1 illustrates the side view of a cross-section along the x-direction (the word line direction, e.g., in the BB plane shown in FIG. 9A-2). FIG. 9A-2 illustrates the plan view of a cross-section in the x-y plane (e.g., in the AA plane through semiconductor walls 905 shown in FIG. 9A-1). The same drawing layout is arranged in FIG. 98-1 and FIG. 9B-2 as well.

In FIG. 9B-1 and FIG. 9B-2, trench isolations 908 (e.g., STIs) are formed in trenches 904. In some implementations, a dielectric, such as silicon oxide, is deposited to fully fill trenches 904 using one or more thin film deposition processes including, but not limited to, CVD, PVD, ALD, or any combination thereof. In some implementations, a planarization process, such as CMP, is performed to remove excess dielectric deposited beyond the top surface of stack 600. As a result, parallel semiconductor walls 905 can be separated by trench isolations 908.

In FIG. 9C-1 and FIG. 9C-2, a plurality of parallel trenches 910 are formed in the x-direction (e.g., the word line direction) to form an array of semiconductor pillars 906 each extending vertically in stack 600.

In some implementations, a lithography process is performed to pattern trenches 910 to be perpendicular to trench isolations 908 using an etch mask (e.g., a photoresist mask and/or a hard mask), for example, based on the design of word lines. One or more dry etching and/or wet etching processes, such as RIE, are performed on semiconductor wall 905 and trench isolation 908 to etch trenches 910 in stack 600. As a result, semiconductor walls 905 (shown in FIG. 9B-1 and FIG. 9B-2) can be cut by trenches 910 to form an array of semiconductor pillars 906 each extending vertically in the stack 600. The third semiconductor layer 604 is used for etching the semiconductor walls 905 to ensure the uniformity of the etch depth and the bottom profile of the portions of the trenches 910 between two neighboring semiconductor pillars 906. The array of semiconductor pillars 906 stand on the third semiconductor layer 604.

FIG. 9C-1 illustrates the side view of a cross-section along the y-direction (the bit line direction, e.g., in the CC plane shown in FIG. 9C-2). FIG. 9C-2 illustrates the plan view of a cross-section in the x-y plane (e.g., in the AA plane through semiconductor pillars 906 shown in FIG. 9C-1).

As shown in the plan view, the two opposite sides of semiconductor pillar 906 in the y-direction are exposed by trenches 910, and the other two opposite sides of semiconductor pillar 906 in the x-direction are in contact with trench isolation 908. In other words, semiconductor pillar 906 is surrounded by trenches 910 and trenches isolations 908.

In FIG. 9D, a plurality of vertical transistors 936 and respective storage units 923 are formed. FIG. 9D illustrates the side view of a cross-section along the bit line direction in a y-z plane.

Gate structures in contact with opposite sides of the semiconductor pillar are formed. In some implementations, to form the gate structures, gate dielectrics are formed over the opposite sides of the semiconductor pillar, and gate electrodes are formed over the gate dielectrics. In some implementations, to form the gate electrodes, conductive layers are deposited over the gate dielectrics, and the conductive layers are etched back.

In FIG. 9D, gate dielectrics 932 are formed over the two opposite sides of semiconductor pillars 906 (shown as semiconductor bodies 935) exposed from trenches 910. In some implementations, gate dielectric 932 is formed by depositing a layer of dielectric, such as silicon oxide, over the sidewalls of trenches 910 using one or more thin film deposition processes including, but not limited to, CVD, PVD, ALD, or any combination thereof, without fully filling trenches 910. It is understood that in some examples, gate dielectrics 932 may not be parts of a continuous dielectric layer. For example, a wet oxidation and/or a dry oxidation process, such as in situ steam generation (ISSG) oxidation, is performed to form native oxide (e.g., silicon oxide) on semiconductor pillar 906 (e.g., single crystalline silicon) as gate dielectric 932.

Conductive layers 934 are formed over gate dielectrics 932 in trenches 910. In some implementations, conductive layers 934 are formed by depositing one or more conductive materials, such as metal and/or metal compounds (e.g., W and TiN), over gate dielectrics 932 using one or more thin film deposition processes including, but not limited to, CVD, PVD, ALD, or any combination thereof, to partially fill trenches 910. For example, layers of TiN and W may be sequentially deposited to form conductive layer 934. A planarization process, e.g., CMP, can be performed to remove the excess conductive materials over the top surface of stack 600.

In some implementations, conductive layers 934 are etched back, for example, using dry etch and/or wet etch (e.g., RIE), to form dents, such that the upper ends of conductive layers 934 are below the top surface of semiconductor pillars 906. In some implementations, as gate dielectrics 932 are not etched back (not shown), the upper ends of conductive layers 934 are below the upper ends of gate dielectrics 932 as well, which are flush with the top surface of semiconductor pillars 906. As a result, etched-back conductive layers 934 can become word lines each extending in the word line direction (the x-direction), and parts of etched-back conductive layers 934 that are facing semiconductor pillars 906 can become gate electrodes. Gate structures each including a respective gate dielectric 932 over the exposed side of semiconductor pillar 906 and a respective gate electrode (part of conductive layer 934) over gate dielectric 932 can be formed thereby. In some implementations, a dielectric layer is formed in the remaining space of trenches 910 as well as the dents (not shown) resulting from etching back of conductive layers 934, for example, by depositing a dielectric, such as silicon oxide, using one or more thin film deposition processes including, but not limited to, CVD, PVD, ALD, or any combination thereof. It is understood that depending on the pitches of the word lines (the dimension of trenches 910), air gaps may be formed in the dielectric layer.

Upper ends of the semiconductor bodies 935 away from the substrate are doped. The exposed upper end of each semiconductor body 935 is doped to form a source/drain (e.g., a source terminal of a vertical transistor). In some implementations, an implantation process and/or thermal diffusion process are performed to dope P-type dopants or N-type dopants to exposed upper ends of semiconductor bodies 935 to form sources/drains. In some implementations, a silicide layer is formed on source/drain by performing a silicidation process at the exposed upper ends of semiconductor bodies 935.

Storage units in contact with the semiconductor bodies, e.g., the doped first ends thereof, are formed. The storage unit can include a capacitor or a PCM element. In some implementations, to form a storage unit that is a capacitor, a first electrode is formed on the doped upper end of the semiconductor body, a capacitor dielectric is formed on the first electrode, and a second electrode is formed on the capacitor dielectric.

For example, one or more interlayer dielectric (ILD) layers are formed over the top surface of stack 600, for example, by depositing dielectrics using one or more thin film deposition processes including, but not limited to, CVD, PVD, ALD, or any combination thereof. Storage unit contact (capacitor contact) 922, first electrodes, capacitor dielectrics, and second electrodes of storage units (capacitors) 923, and a common plate 924 are subsequently formed in the ILD layers to be coupled to semiconductor bodies 935. In some implementations, capacitor contact 922 is formed on a respective source/drain, e.g., the doped upper end of a respective semiconductor body 935 by patterning and etching an electrode hole aligned with respective source/drain using lithography and etching processes and depositing conductive materials to fill the electrode hole using thin film deposition processes. In some implementations, common plate 924 is formed on the second electrodes of capacitors 923 by patterning and etching an electrode trench aligned with capacitors 923 using lithography and etching processes and depositing conductive materials to fill the electrode trench using thin film deposition processes.

FIGS. 9E-91 illustrate a backside fabrication process for forming bit lines from the backside of the semiconductor substrate 602, following the fabrication steps in FIGS. 9A-1/9A-2/9B-1/9B-2/9C-1/9C-2 and 9D. Each of FIGS. 9E-91 illustrates a sideview of a cross-section along the word line direction (the x-direction) in an x-z plane. The cross-section cuts through a row of vertical semiconductor bodies 935 of the respective vertical transistors 936 lined up in the x direction. Compared with FIGS. 9A-1/9A-2/9B-1/9B-2/9C-1/9C-2 and 9D, the sideview in FIGS. 9E-9J are flipped up, and the substrate 601 becomes the top layer in the stack 600. Also, FIGS. 9E-9J only show partial section views of the memory device, and no storage units are illustrated.

FIG. 9E illustrates a partial section view corresponding to the cut line A-A′ in FIG. 9D, and only two semiconductor bodies 935 are illustrated for simplicity. Remaining portions 623 of third semiconductor layer 604 are on top of respective semiconductor bodies 935. The remaining portions 624 of second semiconductor layer 603 are on top of respective remaining portions 623. The structures 623 and 624 extend in the bit line direction (the y-direction). Semiconductor body 935 and the structures 623 and 624 on top thereof are sandwiched between two neighboring trench isolations 908 that extend in the bit line direction.

In FIG. 9F, semiconductor substrate 601 and first semiconductor layer 602 are removed, for example, by performing a planarization process (e.g., CMP), etching process, or any suitable processes. The top surfaces of trench isolations 908 and remaining portions 624 of second semiconductor layer 603 are exposed.

In FIG. 9G, remaining portions 624 of second semiconductor layer 603 are removed during a recess process to expose the top surfaces of the remaining portions 623 of third semiconductor layer 604. Bit line recesses 930 are formed as a result of the recess process. The recess process can be a dry or wet etching process or any suitable process to remove the remaining portions 624. The remaining portions 623 of the third semiconductor layer 604 serves as an etch stop layer during the recess process. Thus, uniformity of the etch depth and bottom etch profile of the bit line recesses 930 can be ensured.

The remaining portion 623 of third semiconductor layer 604 can be used together with a later-formed metal line to form a bit line, and thus is referred to as semiconductor line 623 in the descriptions below in contrast to the later-formed metal line. After forming the bit line recesses 930, the semiconductor lines 623 can be doped with N-type dopants (e.g., P or As) or P-type dopants (e.g., B or Ga) at a desired doping level, by performing an implantation process, a thermal diffusion process, a combination thereof, or any suitable processes. In some implementations, the third semiconductor layer 604 is doped when forming the stack 600 of Si—SiGe layers. The doping in FIG. 9G can be used to further adjust the doping level of the semiconductor lines 623. In some implementations, the doping operation in FIG. 9G can be skipped.

FIGS. 9H-93 illustrate a process for forming a metal line on top of semiconductor line 623 within the bit line recesses 930.

In FIG. 911, a silicide layer 931, such as a metal silicide layer, is formed at the top surface of semiconductor line 623 by performing a silicidation process. The silicide layer may include metal silicides, such as NiSi, TiSi, WSi, CoSi, CuSi, AlSi, or any other suitable metal silicides having higher conductivities than doped silicon. In FIG. 91, a metal layer 938 can be deposited on tops of silicide layers 931 to fill the bit line recessions 930. The metal layer 938 can include W, Co. Cu, Al, or any other suitable metals having higher conductivities than doped silicon. In FIG. 91, the excess part of the metal layer 938 beyond the top surfaces of trench isolations 908 can be removed by performing a planarization process (e.g., CMP). The remaining portions of the metal layer 938 within the bit line recesses 930 can further be recessed by a dry/wet etching process to form a metal line 933 on top of silicide layer 931. In some implementations, an insulating layer is further formed on top of the metal lines 933 to enclose the metal lines 933.

In some implementations, the semiconductor line 623, the silicide layer 931, and the metal line 933 together form a bit line extending in the y-direction. The bit line is positioned on top of the semiconductor bodies 935 and sandwiched between two neighboring trench isolations 908.

### IV. Flowchart of Fabrication Process Using Etch-Stop Layers

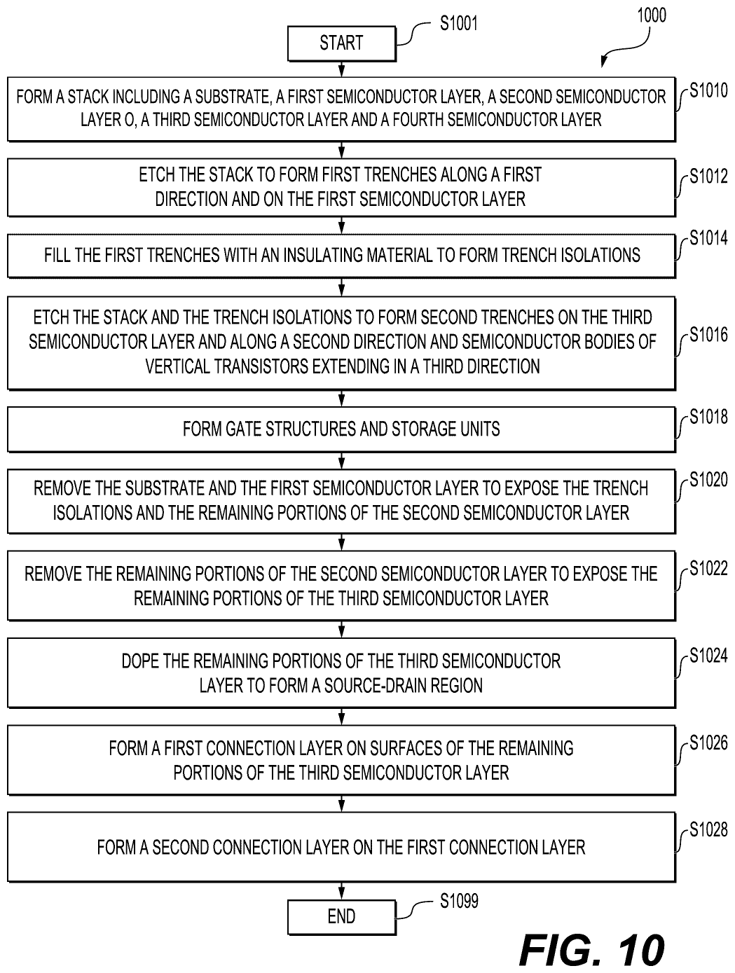

FIG. 10 illustrates a flowchart of a fabrication process 1000 for forming a 3D memory device including vertical transistors, according to some aspects of the present disclosure. The fabrication process 1000 can employ the etch-stop layers introduced herein. The fabrication process 1000 starts from S1001 and proceeds to S1010.

At S1010, a stack of semiconductor layers can be formed over a substrate. The stack can include a first semiconductor layer, a second semiconductor layer over the first semiconductor layer, a third semiconductor layer over the second semiconductor layer, and a fourth semiconductor layer over the third semiconductor layer.

At S1012, the stack is etched through the fourth semiconductor layer, the third semiconductor layer, and the second semiconductor layer to form first trenches along a first direction and on the first semiconductor layer. The second semiconductor layer and the first semiconductor layer can have different etch rates during the etch process, such that the first semiconductor layer can serve as an etch-stop layer during the etch process. High etch selectivity between the second semiconductor layer and the first semiconductor layer is desired.

At S1014, the first trenches are filled with an insulating material to form trench isolations. Remaining portions of the fourth semiconductor layer, the third semiconductor layer, and the second semiconductor layer are sandwiched by neighboring trench isolations.

At S1016, the remaining portions of the fourth semiconductor layer and the trench isolations are etched to form second trenches on the third semiconductor layer and along a second direction perpendicular to the first direction. Also, semiconductor bodies of vertical transistors extending in a third direction and surrounded by the second trenches and the trench isolations are formed. The third direction is perpendicular to the first direction and the second direction. The vertical transistors stand on top of the remaining portions of the third semiconductor layer.

The fourth semiconductor layer and the third semiconductor layer can have different etch rates during the etch process of S1016, such that the third semiconductor layer can serve as an etch-stop layer during the etch process of S1016. High etch selectivity between the fourth semiconductor layer and the third semiconductor layer is desired.

At S1018, gate structures of the vertical transistors coupled to at least one side of the semiconductor bodies along the second direction are formed. The gate structures can each include a dielectric layer and a gate electrode.

At S1020, the substrate and the first semiconductor layer are removed to expose the trench isolations and the remaining portions of the second semiconductor layer.

At S1022, the remaining portions of the second semiconductor layer are removed to expose the remaining portions of the third semiconductor layer that exist at the bottoms of recesses between the neighboring trench isolations, for example, by performing an etch process. The second semiconductor layer and the third semiconductor layer can have different etch rates during the etch process of S1022, such that the third semiconductor layer can serve as an etch-stop layer during the etch process of S1022. High etch selectivity between the second semiconductor layer and the third semiconductor layer is desired.

At S1024, the remaining portions of the third semiconductor layer are doped to form a source-drain region of the vertical transistors.

At S1026, a first connection layer, such as a silicide layer, is formed on surfaces of the third semiconductor layer at the bottoms of the recesses between the neighboring trench isolations.

At S1028, a second layer, such as a bit-line metal, is formed on the first connection layer within the recesses between the neighboring trench isolations. The process proceeds to S1099 and terminates at S1099.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A method of fabricating a memory device, comprising:
forming a stack including
a first semiconductor layer,
a second semiconductor layer over the first semiconductor layer,
a third semiconductor layer over the second semiconductor layer, and
a fourth semiconductor layer over the third semiconductor layer;
etching the stack through the fourth semiconductor layer, the third semiconductor layer, and the second semiconductor layer to form first trenches along a first direction and on the first semiconductor layer;
filling the first trenches with an insulating material to form trench isolations, remaining portions of the fourth semiconductor layer, the third semiconductor layer, and the second semiconductor layer being sandwiched by neighboring trench isolations;
etching the remaining portions of the fourth semiconductor layer and the trench isolations to form second trenches on the third semiconductor layer and along a second direction perpendicular to the first direction and semiconductor bodies of vertical transistors extending in a third direction and being surrounded by the second trenches and the trench isolations, the third direction being perpendicular to the first direction and the second direction, the vertical transistors standing on top of the remaining portions of the third semiconductor layer; and
forming gate structures of the vertical transistors that are along the second direction and coupled to at least one side of the semiconductor bodies.

2. The method of claim 1, further comprising:
removing the first semiconductor layer to expose the second semiconductor layer;
removing the second semiconductor layer to expose the third semiconductor layer that exist at bottoms of recesses between the neighboring trench isolations; and
doping the third semiconductor layer to form a source-drain region of the vertical transistors.

3. The method of claim 2, further comprising:
forming a silicide layer on surfaces of the third semiconductor layer at the bottoms of the recesses between the neighboring trench isolations; and
forming a layer of bit-line metal on the silicide layer within the recesses between the neighboring trench isolations.

4. The method of claim 1, wherein the forming of the stack includes:
epitaxially growing the first semiconductor layer, the second semiconductor layer over the first semiconductor layer, the third semiconductor layer over the second semiconductor layer, and the fourth semiconductor layer over the third semiconductor layer.

5. The method of claim 1, wherein the forming of the stack includes:
epitaxially growing a silicon germanium (SiGe) layer as the third semiconductor layer.

6. The method of claim 1, wherein the forming of the stack includes:
epitaxially growing a SiGe layer as the third semiconductor layer in a way that a concentration of germanium (Ge) decreases upwards at an upper side of the SiGe layer adjacent to the fourth semiconductor layer.

7. The method of claim 1, wherein the forming of the stack includes:
epitaxially growing a SiGe layer as the third semiconductor layer in a way that a concentration of Ge decreases upwards from 20% to 5% at an upper side of the SiGe layer adjacent to the fourth semiconductor layer.

8. The method of claim 1, wherein the forming of the stack includes:
epitaxially growing a SiGe layer with in-situ doping as the third semiconductor layer.

9. The method of claim 1, wherein the forming of the stack includes:
epitaxially growing a SiGe layer as the first semiconductor layer.

10. A memory device, comprising:
an array of memory cells, each memory cell comprising a vertical transistor having a semiconductor body vertically extending in a first direction, each memory cell comprising a storage unit coupled to a first end of the semiconductor body; and
a bit line extending in a second direction perpendicular to the first direction, the bit line connected to second ends of the semiconductor bodies of a row of the vertical transistors, the bit line comprising a semiconductor epitaxial layer extending in the second direction and connected to the second ends of the semiconductor bodies of the row of the vertical transistors at a top surface of the semiconductor epitaxial layer.

11. The memory device of claim 10, wherein the bit line further comprises:
a first connection layer extending in the second direction and covering a bottom surface of the semiconductor epitaxial layer, and
a third connection layer below and adjacent to the first connection layer and extending in the second direction.

12. The memory device of claim 10, wherein the bit line further comprises:
a silicide layer extending in the second direction and covering a bottom surface of the semiconductor epitaxial layer, and
a metal layer below and adjacent to the silicide layer and extending in the second direction.

13. The memory device of claim 10, wherein the semiconductor epitaxial layer is a silicon germanium (SiGe) epitaxial layer.

14. The memory device of claim 10, wherein a concentration of germanium (Ge) decreases upwards in the first direction at an upper side of the semiconductor epitaxial layer.

15. The memory device of claim 10, wherein a first concentration of germanium (Ge) at a first position is greater than a second concentration of Ge at a second position, the first position being below the second position along the first direction at an upper side of the semiconductor epitaxial layer.

16. The memory device of claim 10, wherein a concentration of Ge decreases upwards from 20% to 5% in the first direction at an upper side of the semiconductor epitaxial layer.

17. The memory device of claim 10, wherein a first concentration of Ge at a first position is in a range of 25%-15%, and a second concentration of Ge at a second position is in a range of 10%-2%, the first position being below the second position in the first direction at an upper side of the semiconductor epitaxial layer.

18. The memory device of claim 10, wherein the semiconductor epitaxial layer is doped with n-type or p-type dopants.

19. The memory device of claim 10, further comprising:
a plurality of word lines, each word line extending in a third direction perpendicular to the first direction and the second direction, each word line being coupled to gate structures of the respective vertical transistors.

20. A memory system, comprising:
a memory controller; and
a memory device coupled to the memory controller, the memory device comprising:
an array of memory cells, each memory cell comprising a vertical transistor having a semiconductor body vertically extending in a first direction, each memory cell comprising a storage unit coupled to a first end of the semiconductor body, and
a bit line extending in a second direction perpendicular to the first direction, the bit line connected to second ends of the semiconductor bodies of a row of the vertical transistors, the bit line comprising a semiconductor epitaxial layer extending in the second direction and connected to the second ends of the semiconductor bodies of the row of the vertical transistors at a top surface of the semiconductor epitaxial layer.
